(19) United States
(12) Patent Application Publication
(10) Pub. No.: US 2013/0271936 A1
(43) Pub. Date: Oct. 17, 2013

(54) ELECTRONIC DEVICE HAVING KEY ASSEMBLY

(71) Applicants: XUE-DONG TANG, Shenzhen City (CN); WEI LIU, Shenzhen City (CN)

(72) Inventors: XUE-DONG TANG, Shenzhen City (CN); WEI LIU, Shenzhen City (CN)

(73) Assignees: HON HAI PRECISION INDUSTRY CO., LTD, Tu-Cheng (TW); HONG FU JIN PRECISION INDUSTRY (ShenZhen) CO., LTD, Shenzhen City (CN)

(21) Appl. No.: 13/570,227

(22) Filed: Aug. 8, 2012

(30) Foreign Application Priority Data
Apr. 11, 2012 (CN) 201210103989.X

(51) Int. Cl. H05K 7/02

(52) U.S. Cl. 361/759

(57) ABSTRACT

An electronic device includes a housing defining at least one mounting hole, a key assembly secured to the housing, and a circuit board housed in the housing. A securing mechanism is secured to the housing and is used to hold the key assembly for preventing the key assembly from moving in a first direction. The circuit board abuts the key assembly to prevent the key assembly from moving in a second direction perpendicular to the first direction when fixed to the housing.

### BACKGROUND

1. Technical Field

The present disclosure relates to electronic devices, and particularly to an electronic device having a key assembly.

2. Description of Related Art

Electronic devices, such as DVD players, include a housing, a circuit board housed in the housing, and a plurality of keys mounted on the housing. Each key abuts a switch electrically connected to the circuit board. However, because the electronic devices are becoming thinner, during the assembling process of the electronic device, only a very limited space is provided for mounting the keys, which is inconvenient.

Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the six views.

FIG. 1 is a partial perspective view of an electronic device having a key assembly in accordance with an embodiment.

FIG. 2 is a partially disassembled view of the electronic device of FIG. 1.

FIG. 3 is a perspective view of the key assembly of the electronic device of FIG. 1.

FIG. 4 is similar to FIG. 3, but viewed from another aspect.

FIGS. 5-6 are partial assembly views of the electronic device of FIG. 2.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one”.

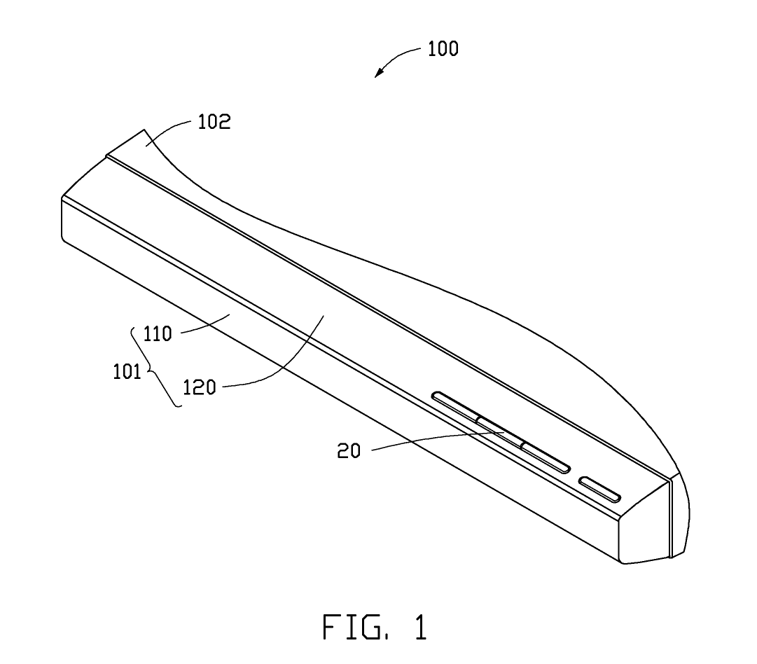

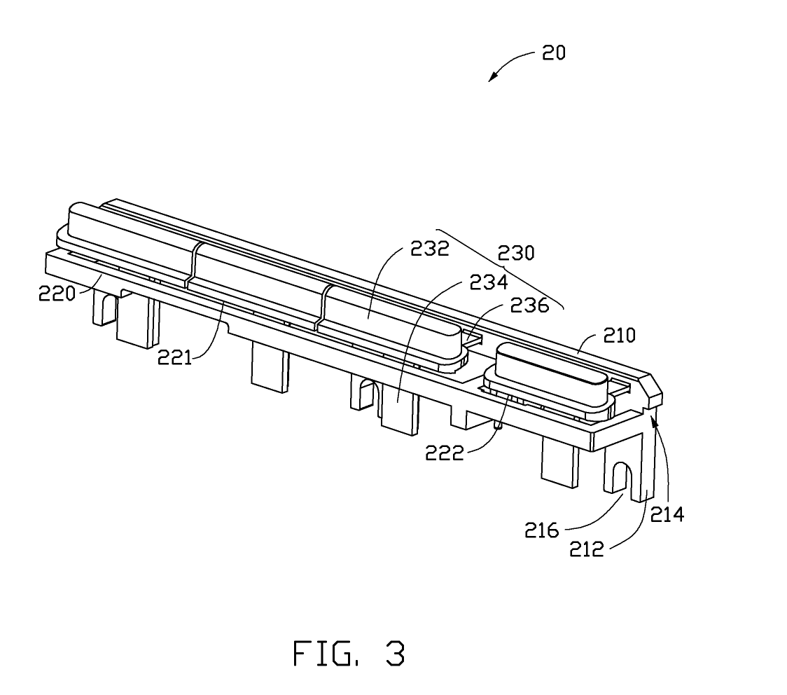

Referring to FIG. 1, an electronic device 100 is shown. The electronic device 100 includes a housing 10, a key assembly 20 mounted to the housing 10, and a circuit board 30 housed in the housing 10. The key assembly 20 includes four keys 230 in the embodiment (see FIG. 3).

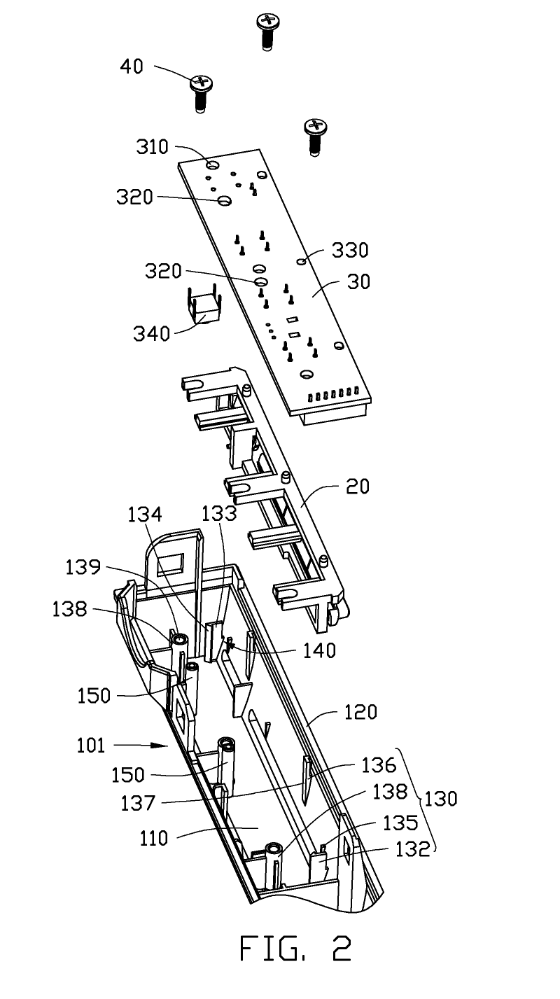

Referring also to FIG. 2, the housing 10 includes a front case 101 and a rear case 102. The front case 101 engages with the rear case 102 to define an accommodating space (not labeled) for receiving circuit board 30 and other electronic components (not shown) of the electronic device 100. The front case 101 includes a substantially rectangular front wall 110 and four sidewalls 120 extending from rims of the front wall 110. One of the sidewalls 120 (referred herein as the first sidewall 120) defines two mounting holes 121. The mounting holes 121 are substantially slit-shaped and extend in a direction parallel to the front wall 110. The mounting holes 121 are aligned parallel to the front wall 110. In the embodiment, the mounting holes 121 are spaced from each other. In another embodiment, the mounting holes 121 communicate with each other to form an integral hole.

A securing mechanism 130 is mounted on an inner surface of the front case 101. The securing mechanism 130 is used for securing the key assembly 20 to the front case 101. The securing mechanism 130 includes two hook portions 132, three protrusions 135, two clipping members 136 and three fixing posts 138.

The hook portions 132 are arranged at opposite sides of the mounting holes 121. Each hook portions 132 includes a limiting plate 133 and a hook 134. The limiting plate 133 is perpendicularly secured to an inner surface of the front wall 110 and further connects with the first sidewall 120. The hooks 134 protrude from ends of the limiting plates 133 away from the first sidewall 120 and extend toward each other. The hooks 134 are substantially perpendicular to the front wall 110.

The protrusions 135 are secured to an inner surface of the first sidewall 120 and are arranged between the limiting plates 133. The protrusions 135 are aligned parallel to the front wall 110. Distance between the protrusions 135 and the front wall 110 is less than the distance between the front wall and ends of the hook portions 132 away from the front wall 110.

The clipping members 136 are secured to an inner surface of the first sidewall 120 and are arranged between the limiting plates 133. Each clipping member 136 defines an abutting end 137 opposite to the first sidewall 120 and parallel to the hooks 134. The abutting ends 137 cooperate with the hooks 134 and the limiting plates 133 to define a clipping space 140. The fixing posts 138 are perpendicularly secured to the inner surface of the front wall 110. The fixing posts 138 are aligned parallel to the first sidewall 120. Each fixing post 138 defines a fixing hole 139.

Two limiting posts 150 are secured to the inner surface of the front wall 150. The limiting posts 150 are substantially aligned with the fixing posts 138. The height of the limiting posts 150 relative to the front wall 110 is greater than that of the fixing posts 138.

The circuit board 30 is substantially rectangular, and is parallel to the front wall 110. The circuit board 30 defines three round holes 310 corresponding to the fixing holes 139 and two through holes 320 for receiving the limiting posts 150. The circuit board 30 further defines three limiting holes 330. The limiting holes 330 are aligned parallel to a rim of the circuit board 30 adjacent to the first sidewall 120. Four switches 340 are electrically connected to the circuit board 30. The switches 340 correspond to the keys 230 and each one is actuated when pressed by the corresponding key 230.

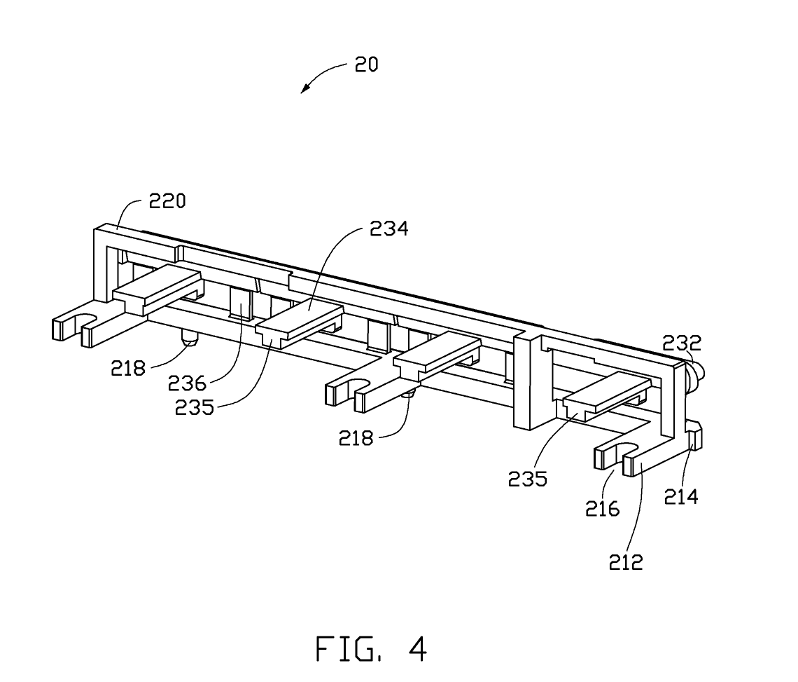

Referring to FIGS. 3-4, the key assembly 230 includes a base 210, a limiting portion 220, and four keys 230 secured to the base 210. The base 210 is substantially strip shaped. The length of the base 210 is slightly less than the distance between the limiting plates 133, and the width of the base 210 is slightly less than the distance between longitudinal planes of the hooks 134 and the abutting ends 137. Three fixing arms 212 protrude from the base 310 extending in longitudinal direction and correspond to the fixing posts 318. The fixing arms 212 are aligned parallel to the base 310. One of the fixing arms 212 is arranged at the middle of the base 310, and the other two fixing arms 212 are arranged adjacent to opposite ends of the base 310 to form two steps 214. The steps 214 correspond to the hooks 134. When the base 210 is received between the limiting plates 133, the steps 214 are latched by the hooks 134 and the abutting ends 317 abut an end of the base 210 opposite to the fixing arms 212, to hold the base 210 in the clipping space 140. An end of each fixing arm 212 away from the base 210 defines a substantially U-shaped recess 216. The recesses 216 correspond to the fixing holes 319. Three protruding posts 218 are secured to a side of the base 210. The protruding posts 218 are spaced from each other and correspond to the limiting holes 330.

The limiting portion 220 is perpendicularly secured adjacent to ends of the fixing arms 212 connecting with the base 210 and are opposite to the protruding posts 218. The limiting portion 220 defines two openings 221 corresponding to the mounting holes 121.

The keys 230 are secured to the base 210 and are arranged at a side of the limiting portion 220 opposite to the recesses 216. In the embodiment, three keys 230 correspond to one of the through holes 222 and one of the mounting holes 121, and the other key 230 corresponds to the other through hole 222 and the other mounting hole 121. Each key 230 includes an operating portion 232 which can be pressed by a fingertip, an actuating post 234 secured to the operating portion 232 and perpendicular to the limiting portion 220, and two connecting arms 236 for connecting the operating portion 232 with the base 210. The connecting arms 236 are perpendicular to the base 210 and parallel with the limiting portion 220. The connecting arms 236 are made of elastic material for providing an elastic force to restore the operating portion 232 to its original position when the operating portion 232 is released. The distance between the base 210 and an end of the operating portion 232 away from the base 210 is greater than the distance between the base 210 and an edge of the openings 221 away from the base 210, thus, when the operating portion 232 is pressed, the limiting portion 220 abuts the operating portion 232 to protect the key assembly 20 from being damaged by excessive pressure. Ends of the actuating posts 340 away from the operating portions 232 abut the switches 340, to actuate the switches 340 when the operating portions 232 are pressed.

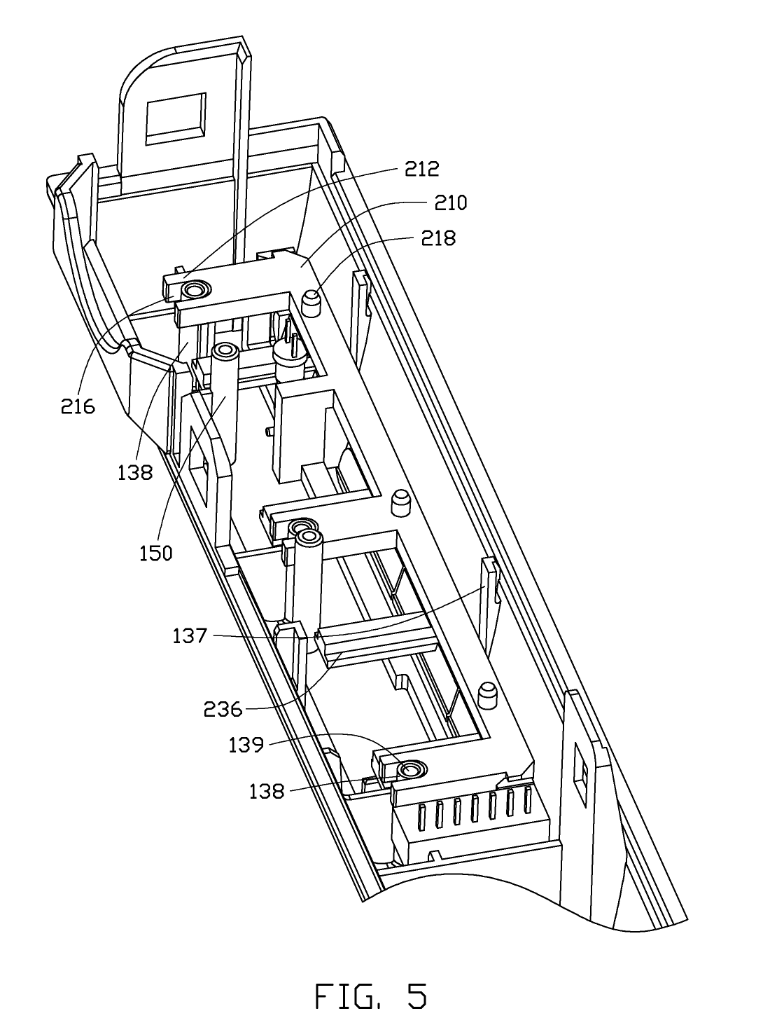

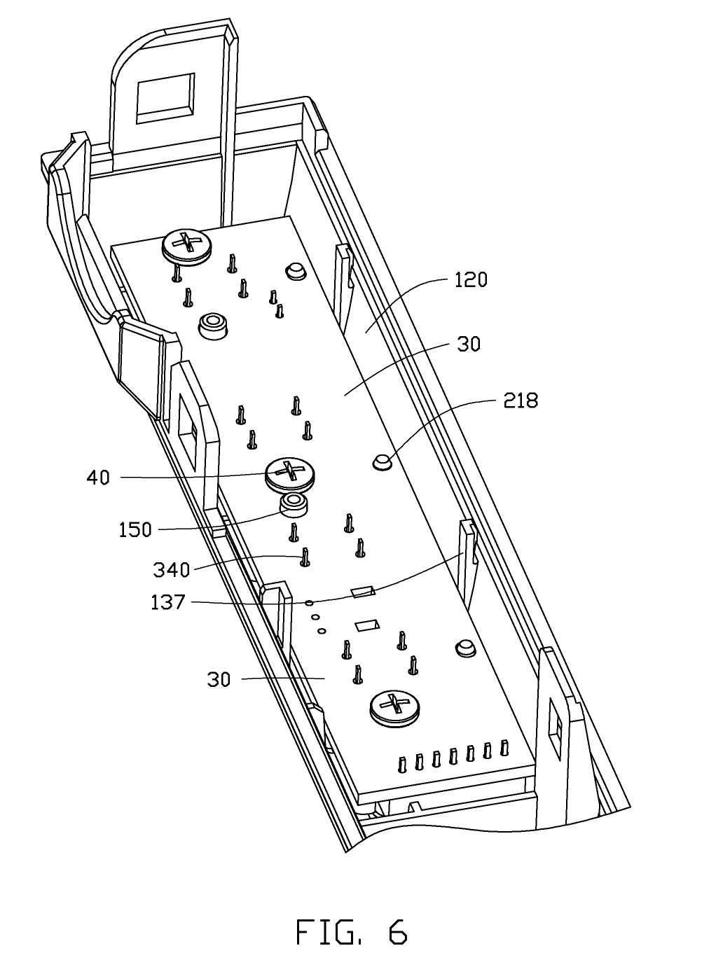

Referring to FIGS. 5-6, in assembly, the base 210 is arranged between the limiting plates 133 with the steps 214 being latched by the hooks 134 and the fixing posts 138 being received in the recesses 216. The base 210 is further pressed till the base 210 is abutted by the protrusions 135. At this time, the operating portions 232 are received in their respective mounting holes 121, and the key assembly 20 is positioned to the front case 101. The circuit board 30 is placed on the key assembly 20, the round holes 310 correspond to the fixing holes 139, the through holes 320 receive the limiting posts 150, and the limiting holes 330 receive the protruding posts 218. Finally, fixing members, such as screws 40 extend through the round holes 310 and are further threaded into the fixing holes 139, the circuit board 30 is thus fixed to the front case 101 and abuts the key assembly 20.

After assembly, opposite ends of the base 210 are limited by the hook portions 133, the fixing posts 138 abut the fixing arms 212 and the abutting ends 137 abut a side of the base 210 opposite to the fixing arms 212, and thus, the key assembly 20 is prevented from moving in a direction parallel to the front wall 110. The circuit board 30 and the protrusions 135 abut opposite surfaces of the base 210, thus, the key assembly 20 is prevented from moving in a direction perpendicular to the front wall 110. As a result, the key assembly 20 is held captive and unmoving in the housing 10. Furthermore, the limiting posts 150 are received in the through holes 320 and the protruding posts 218 are received in the limiting holes 330, thus, the circuit board 30 is prevented from rotating after fixed to housing 10.

By virtue of the fixing mechanism 130, the key assembly 20 is easily secured to the housing 10 after the circuit board 30 is fixed, and the small size of the key assembly 20 allows fixing in a very limited space of the electronic device 100.

It is to be understood, even though information as to, and advantages of, the present embodiments have been set forth in the foregoing description, together with details of the structures and functions of the present embodiments, the disclosure is illustrative only; and that changes may be made in detail, especially in the matters of shape, size, and arrangement of parts within the principles of the present embodiments to the full extent indicated by the broad general meaning of the terms in which the appended claims are expressed.

What is claimed is:

1. An electronic device, comprising:
a housing comprising a front wall and a first sidewall extending from a rim of the front wall, the first sidewall defining at least one mounting hole;
a key assembly secured to the housing, the key assembly comprising a base and at least one key secured to the base and received in the at least one mounting hole; and
a circuit board housed in the housing;
wherein a securing mechanism is secured to the housing, the securing mechanism comprises two hook portions secured to the front wall and arranged at opposite sides of the at least one mounting hole, and at least one clipping member arranged between the hook portions; the hook portions cooperate with the at least one clipping member to prevent the key assembly from moving in a first direction parallel to the front wall; the circuit board abuts the key assembly to prevent the key assembly from moving in a second direction perpendicular to the front wall when fixed to the housing.

2. The electronic device of claim 1, wherein the securing mechanism further comprise at least fixing arm, the at least one fixing arm is secured to the base and cooperates with opposite ends of the base to form two steps engaging with the hook portions.

3. The electronic device of claim 2, wherein the securing mechanism further comprises at least one fixing posts secured to the front wall, the at least one fixing post is used to fix the circuit board to the housing and further abuts an end of the at least one fixing arm away from the base.

4. The electronic device of claim 1, wherein the securing mechanism further comprises at least one protrusion, the at least one protrusion is arranged between the hook portions, the at least one protrusion and the circuit board abut opposite sides of the key assembly to prevent the key assembly from moving in the second direction perpendicular to the front wall.

5. The electronic device of claim 1, wherein each key comprises an operating portion, an actuating posts secured to the operating portion, and at least one connecting arm connecting the operating portion to the base.

6. The electronic device of claim 5, wherein at least one switch is electrically connected to the circuit board and abut the operating portion, the at least one switch is actuated when the operating portion is pressed.

7. The electronic device of claim 5, wherein the at least one connecting arm is made of elastic material.

8. The electronic device of claim 5, wherein the key assembly further comprises a limiting portion secured to the base, the limiting portion is used for protecting the at least one key from being damaged by excessively pressure.

9. The electronic device of claim 1, wherein at least one protruding post is secured to a side of the base opposite to the at least one key.

10. The electronic device of claim 9, wherein the circuit board further defines at least one limiting hole, the at least one limiting hole receive the at least one protruding post when the circuit board is fixed to the housing.

11. The electronic device of claim 1, wherein at least one limiting post is secured to an inner surface of the front wall for preventing the circuit board from rotating.

12. The electronic device of claim 11, wherein the circuit board further defines at least one through hole for receiving the at least one limiting post.
